(19) United States
(12) Patent Application Publication
(10) Pub. No.: US 2012/0153318 A1
(43) Pub. Date: Jun. 21, 2012

(54) WHITE LIGHT ELECTROLUMINESCENCE DEVICE

(75) Inventors: Chang-Yen Wu, Taipei City (TW); Chun-Liang Lin, New Taipei City (TW); Chieh-Wei Chen, Taichung City (TW); Chung-Chun Lee, Yunlin County (TW)

(73) Assignee: AU OPTRONICS CORPORATION, Hsinchu (TW)

(21) Appl. No.: 13/069,372

(22) Filed: Mar. 22, 2011

(30) Foreign Application Priority Data
Dec. 19, 2010 (TW) 99146635

(51) Int. Cl. H01L 33/08

(52) U.S. Cl. 257/89; 257/E33.012

(57) ABSTRACT

A white light electroluminescence device includes a first light emitting unit, a second light emitting unit and a connecting layer between the first and the second light emitting units. The connecting layer electrically connects the first and the second light emitting units in series. The first light emitting unit includes a first electrode layer and a first light emitting layer on the first electrode layer, wherein the first light emitting layer includes a first blue light emitting layer and a red light emitting layer having a first co-host material and a first dopant material. The second light emitting unit includes a second light emitting layer and a second electrode layer on the second light emitting layer, wherein the second light emitting layer has a second blue light emitting layer and a green light emitting layer having a second co-host material and a second dopant material.

### CROSS-REFERENCE TO RELATED APPLICATION

This application claims the priority benefit of Taiwan application serial no. 99146635, filed Dec. 19, 2010. The entirety of the above-mentioned patent application is hereby incorporated by reference herein and made a part of this specification.

### BACKGROUND OF THE INVENTION

1. Field of the Application

The present invention relates to a light emitting device, and more particularly, to a white light electroluminescence device.

2. Description of Related Art

As the semiconductor technology advances, modern light emitting diodes (LEDs) already have outputs with high brightness. Along with the advantages such as energy saving, small volume, low driving voltage and mercury-free, the light emitting diodes are already widely applied in the fields of displays and lighting. Generally, a common white light LED device utilizes the light emitted by a blue light LED. By adding fluorescent materials of different colors and ratios, the light color irradiated by the excitation of those materials excited by a portion of blue light is different from the color of the blue light LED and is utilized. The light color is then mixed with the remaining blue light such that the white light with different chromaticity is generated. This is the most general technique for the application of generating white light currently.

In order to prolong the life span of a white light electroluminescence device, a stacked white light electroluminescence device has been provided presently. The device is constituted by stacking light emitting diodes of different light color together, such that the light color emitted from the device can be mixed to become white light. However, it is difficult to adjust the light color of white light in a stacked white light emitting diode device. Therefore, it is hard to satisfy the requirements of different light color of white light in lighting application.

### SUMMARY OF THE INVENTION

The present invention provides a white light electroluminescence device capable of easily adjusting the light color of the white light to satisfy different requirements of the light color of white light in lighting application.

A white light electroluminescence device is provided, which comprises a first light emitting unit, a second light emitting unit and a connecting layer between the first light emitting unit and the second light emitting unit. The connecting layer electrically connects the first light emitting unit and the second light emitting unit in series. The first light emitting unit comprises a first electrode layer and a first light emitting layer disposed on the first electrode layer, wherein the first light emitting layer comprises a first blue light emitting layer and a red light emitting layer, and the red light emitting layer comprises a first co-host material and a first dopant material. The second light emitting unit comprises a second light emitting layer and a second electrode layer disposed on the second light emitting layer, wherein the second light emitting layer comprises a second blue light emitting layer and a green light emitting layer. The green light emitting layer comprises a second co-host material and a second dopant material.

Based on the above, the first light emitting unit of the present invention comprises a first blue light emitting layer and a red light emitting layer, wherein the red light emitting layer comprises a first co-host material and a first dopant material. In addition, the second light emitting unit comprises a second blue light emitting layer and a green light emitting layer, wherein the green light emitting layer comprises a second co-host material and a second dopant material. By adjusting the percentage of the first co-host material in the first light emitting layer and the percentage of the second co-host material in the second light emitting unit, the white light electroluminescence device can irradiate white light with the desired light color.

In order to make the aforementioned and other features and advantages of the invention more comprehensible, several embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 shows a schematic cross-sectional view of a white light electroluminescence device according to one embodiment of the present invention.

FIG. 2 and FIG. 3 show the relationships between light emitting wavelengths and the light emitting intensity under the conditions of different percentages of host materials in the red light emitting layer of the first light emitting unit.

FIG. 4 shows the relationship between light emitting wavelengths and the light emitting intensity under the conditions of different percentages of host materials in the green light emitting layer of the second light emitting unit.

### DESCRIPTION OF EMBODIMENTS

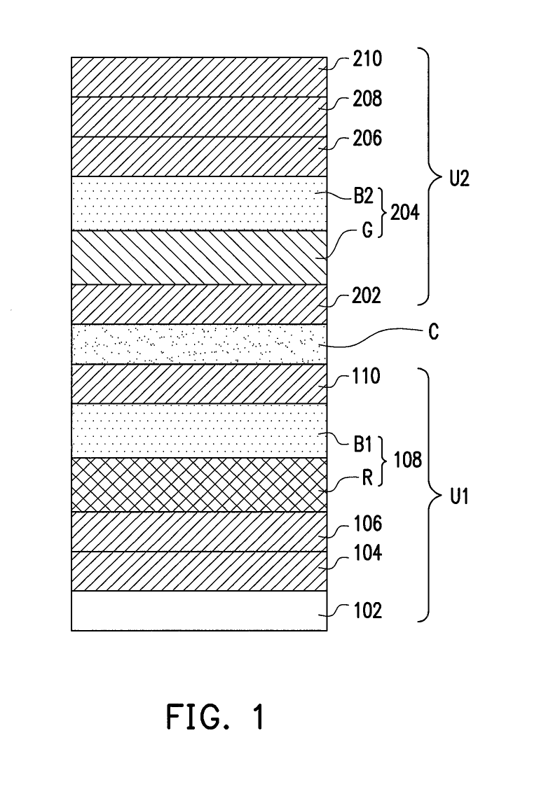

FIG. 1 shows a white light electroluminescence device according to one embodiment of the present invention. Referring to FIG. 1, the white light electroluminescence device of this embodiment comprises a first light emitting unit U1, a second light emitting unit U2 and a connecting layer C disposed between the first light emitting unit U1 and the second light emitting unit U2.

The first light emitting unit U1 comprises a first electrode layer 102 and a first light emitting layer 108. According to this embodiment, the first electrode layer 102, for example, is a transparent conductive layer, and a material of which comprises metal oxides such as Indium-Tin oxide (ITO), Indium-Zinc oxide (IZO), Gallium-Zinc oxide (GZO), Zinc-Tin oxide (ZTO) or other metal oxides.

The first light emitting layer 108 is disposed on the first electrode layer 102, and the first light emitting layer 108 comprises a first blue light emitting layer B1 and a red light emitting layer R. The first blue light emitting layer B1 can be disposed on the red light emitting layer R, or the red light emitting layer is disposed on the first blue light emitting layer B1. The material of the first blue light emitting layer B1 can be blue fluorescent materials or blue phosphor materials. The material of the red light emitting layer R can be red fluorescent materials or red phosphor materials.

According to this embodiment, the first blue light emitting layer B1 comprises a host material and a dopant material. For example, the host material of the first blue light emitting layer B1 can be 2,6-bis(3-(carbazol-9-yl)phenyl)pyridine (26DCzPPy) or bis-4-(N-carbazolyl)phenyl)phenylphosphine oxide (BCPO), and the dopant material of the first blue light emitting layer B1 can be Firpic or Fir6. In addition, the ratio of the host material to the dopant material in the first blue light emitting layer B1 is 0.7:0.3˜0.95:0.05. Besides, the thickness of the first blue light emitting layer B1, for example, is 5-20 nm.

In addition, the red light emitting layer R comprises a first co-host material and a first dopant material. According to this embodiment, the percentage of the first co-host material in the red light emitting layer R is 90˜99.5 wt %, and the percentage of the first dopant material is 0.5˜1.0 wt %. Particularly, the first co-host material of the red light emitting layer R comprises a first host material and a second host material, and the percentage of the second host material in the first co-host material is 5˜60 wt %. According to this embodiment, the first host material can be 4,4′-bis(diphenylphosphoryl)biphenyl (PO1) or Bis(2-methyl-8-quinolinolato-N1,O8)-(1,1′-Biphenyl-4-olato)aluminum (BAIq), and the second host material can be 4,4′,4″-tris(N-carbazolyl)triphenylamine (TCTA) or 4,4-bis(carbazol-9-yl)biphenyl (CBP). The first dopant material can be tris(1-phenylisoquinoline) iridium (Ir(piq)₃) or bis(1-(phenyl)isoquinoline) iridium (III) acetylanetonate (Ir(piq)₂(acac)). In general, the second host material (such as TCTA) is also called a p-type host material. Besides, the thickness of the red light emitting layer, for example, is 5˜35 nm.

The second light emitting unit U2 comprises a second light emitting layer 204 and a second electrode layer 210. The second light emitting layer 204 comprises a second blue light emitting layer B2 and a green light emitting layer G. The second blue light emitting layer B2 can be disposed on the green light emitting layer G, or the green light emitting layer G is disposed on the second blue light emitting layer B2. The material of the second blue light emitting layer B2 can be blue fluorescent materials or blue phosphor materials. The material of the green light emitting layer G can be green fluorescent materials or green phosphor materials.

According to this embodiment, the second blue light emitting layer B2 comprises a host material and a dopant material. For example, the host material of the second blue light emitting layer B2 can be 26DCzPPy or 2,8-bis(diphenylphosphoryl)dibenzothiophene (PO15)., and the dopant material of the second blue light emitting layer B2 can be Bis(4,6-difluorophenyl-pyridine)(picolinate)iridium(III) (Firpic) or iridium bis (4,6-difluorophenylpyridinato-N, C2′)[5-(2-pyridyl)tetrazolate] (FIrN4). In addition, the ratio of the host material to the dopant material in the second blue light emitting layer B2 is 0.7:0.3˜0.95:0.05. Besides, the thickness of the second blue light emitting layer, for example, is 5-30 nm. In other words, in this embodiment, the material of the blue light emitting layer B2 and the material of the first blue light emitting layer B1 in the first light emitting unit U1 can be substantially the same; however, the present invention is not limited thereto. According to other embodiments, the material of the second blue light emitting layer B2 can be different from that of the first blue light emitting layer B1.

In addition, the green light emitting layer G comprises a second co-host material and a second dopant material. According to this embodiment, the percentage of the second co-host material in the green light emitting layer G is 75˜97 wt %, and the percentage of the second dopant material is 3˜25 wt %. Particularly, the second co-host material of the green light emitting layer G comprises a third host material and a fourth host material, and the percentage of the fourth host material in the second co-host material is 60˜100 wt %. According to this embodiment, the material of the third host material can be BAlq or bis(3-ami-nophenyl) phosphinic acid phenylester (PO2), and the material of the fourth host material can be TCTA or 1,3-bis(9-carbazolyl)benzene (mCP). In addition, the second dopant material can be Iridium, tris(2-phenylpyidine) (Ir(ppy3)) or fac-tris[5-fluoro-2(5-trifluoromethyl-2-pyridinyl)phenyl-C,N]iridium (Ir-2h). In general, the fourth host material (such as TCTA) is also called a p-type host material. Besides, the thickness of the green light emitting layer, for example, is 5˜35 nm.

It should be noted that in this embodiment, the second host material (such as TCTA) of the red light emitting layer G in the first light emitting unit U1 and the fourth host material (such as TCTA) of the green light emitting layer G in the second light emitting unit U2 are substantially the same. However, the present invention is not limited to this example.

In addition, the second electrode layer 210 is disposed on the second light emitting layer 204. According to this embodiment, the second electrode layer 210 comprises metal electrode materials such as Aluminum (Al), Aluminum/Lithium (Al/Li) alloy, Magnesium/Silver (Mg/Ag) alloy, or other metal materials. The thickness of the second electrode layer 210, for example, is 150 nm.

In addition, the connecting layer C is disposed between the first light emitting unit U1 and the second light emitting unit U2, such that the first light emitting unit U1 and the second light emitting unit U2 are electrically connected together in series. According to this embodiment, the connecting layer C comprises conductive materials such as Li or Cs.

Besides, in this embodiment, in order to increase the combination rate of electrons and holes of the first light emitting layer 108 in the first light emitting unit U1 to improve the light emitting efficiency of the first light emitting unit U1, a first hole injection layer 104 is further disposed between the first electrode layer 102 and the first light emitting layer 108; a hole transport layer 106 is disposed between the first electrode layer 102 and the first light emitting layer 104; and a first electron transport layer 110 is disposed between the connecting layer C and the first light emitting layer 108. According to this embodiment, the first hole injection layer 104 can be a hole transport material doped with P-type dopants, and the first hole transport layer 106 can be an undoped hole transport material. Similarly, in order to increase the combination rate of electrons and holes of the second light emitting layer 204 in the second light emitting unit U2 to improve the light emitting efficiency of the second light emitting unit U2, a second hole transport layer 202 is further disposed between the second light emitting layer 204 and the connecting layer C; a second electron injection layer 206 is disposed between the second light emitting layer 204 and the second electrode layer 210; and a second electron transport layer 208 is disposed between the second light emitting layer 204 and the second electrode layer 210. According to this embodiment, the second electron injection layer 206 can be an electron transport material doped with P-type dopants, and the second electron transport layer 208 can be an undoped electron transport material.

It should be noted that the present invention is not limited to the necessity of disposing the electron injection layers, the electron transport layers, the hole injection layers and the hole transport layers in the first light emitting unit U1 and the second light emitting unit U2. The present invention is also not limited to the number of layers of the electron injection layers, the electron transport layers, the hole injection layers and the hole transport layers disposed in the first light emitting unit U1 and the second light emitting unit U2. In other words, according to the selection of material of the first electrode layer 102, the first light emitting layer 108, the second light emitting layer 204 and the second electrode layer 210 in the first light emitting unit U1 and the second light emitting unit U2, and the material of the connecting layer C, the arrangements of the desired electron injection layers, electron transport layers, hole injection layers and hole transport layers could be determined in practice.

In addition, in the embodiment illustrated in FIG. 1, the second light emitting unit U2 is disposed on the first light emitting unit U1 as an example. However, the present invention is not limited to the example. According to other embodiments, the first light emitting unit U1 can also be disposed on the second light emitting unit U2, or the first light emitting layer 108 can be disposed in the second light emitting unit U2, and the second light emitting layer 204 can be disposed in the first light emitting unit U1 (that is, to exchange the positions of the first light emitting layer 108 and the second light emitting layer 204).

As described above, in the first light emitting layer 108 of the first light emitting unit U1 of this embodiment, the first co-host material of the red light emitting layer R comprises a first host material and a second host material, and the percentage of the second host material in the first co-host material is 5˜60 wt %. By adjusting the percentages (5˜60 wt %) of the first host material and the second host material in the first co-host material, the light emitting intensity of blue light irradiated by the first light emitting unit U1 could be different.

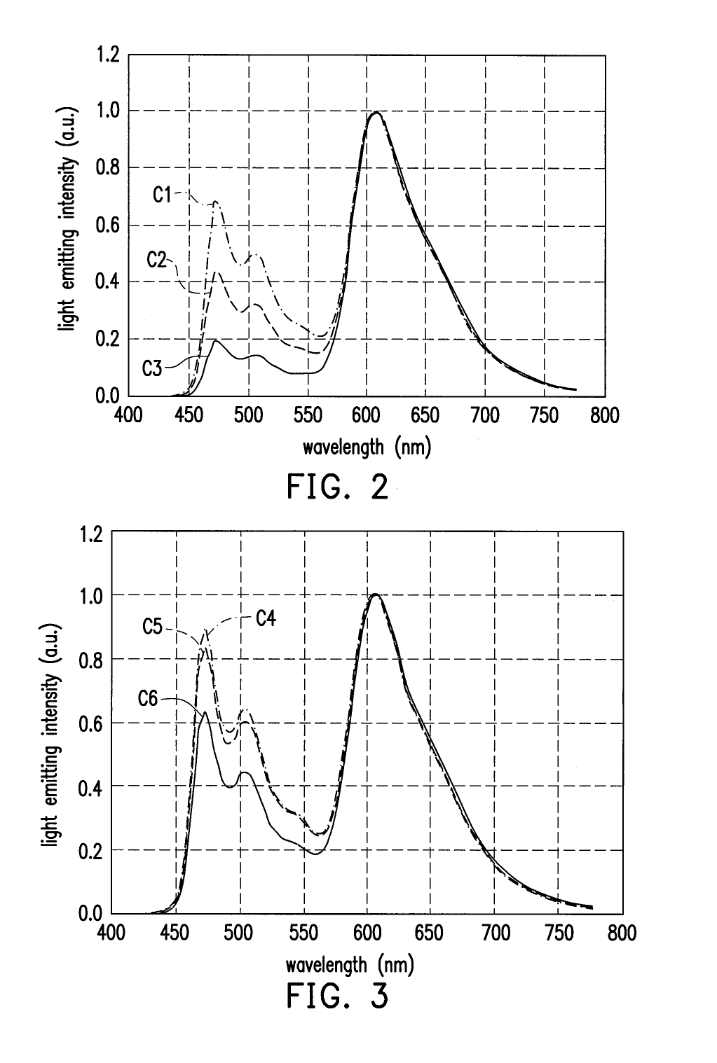

As shown in FIG. 2, C1, C2 and C3 respectively represent the relation curves of the light emitting wavelengths and the light emitting intensity of three first light emitting units U1. Particularly, in the first light emitting units U1 represented by C1, C2 or C3, the first light emitting layer 108 has a first blue light emitting layer B1 and a red light emitting layer R, and C1, C2 and C3 represent that the percentages of the second host material (TCTA) in the first co-host material (BAlq+TCTA) of the red light emitting layer R in the first light emitting unit U1 are respectively 30 wt %, 20 wt %, and 10 wt %. In FIGS. 3, C4, C5 and C6 respectively represent the relation curves of the light emitting wavelengths and the light emitting intensity of three first light emitting units U1. Particularly, in the first light emitting units U1 represented by C4, C5 and C6, the first light emitting layer 108 has a first blue light emitting layer B1 and a red light emitting layer R, and C4, C5 and C6 represent that the percentages of the second host material (TCTA) in the first co-host material (BAlq+TCTA) of the red light emitting layer R in the first light emitting unit U1 are respectively 60 wt %, 50 wt %, and 40 wt %. Particularly, in the first light emitting units U1 represented by C1˜C6, except the ratios between the second host material and the first host material of the red light emitting layer R are different, the conditions of other membrane layers are the same.

It can be known from FIG. 2 and FIG. 3 that when the percentage of the second host material in the red light emitting layer R of the first light emitting unit U1 becomes higher, the intensity of the blue light (440 nm˜480 nm) irradiated by the first light emitting unit U1 would become stronger, and the intensity of the red light (590 nm˜650 nm) of the first light emitting unit U1 almost remains the same. In other words, in this embodiment, by adjusting the percentages of the first host material and the second host material in the red light emitting layer R of the first light emitting unit U1, the intensity of the blue light irradiated by the first light emitting unit U1 can be different.

Similarly, in the second light emitting layer 204 of the second light emitting unit U2 of this embodiment, the second co-host material of the green light emitting layer G comprises a third host material and a fourth host material, and the percentage of the fourth host material in the second co-host material is 60˜100 wt %. By adjusting the percentages (60˜100 wt %) of the third host material and the fourth host material in the second co-host material, the light emitting intensity of the green light irradiated by the second light emitting unit U2 can be different.

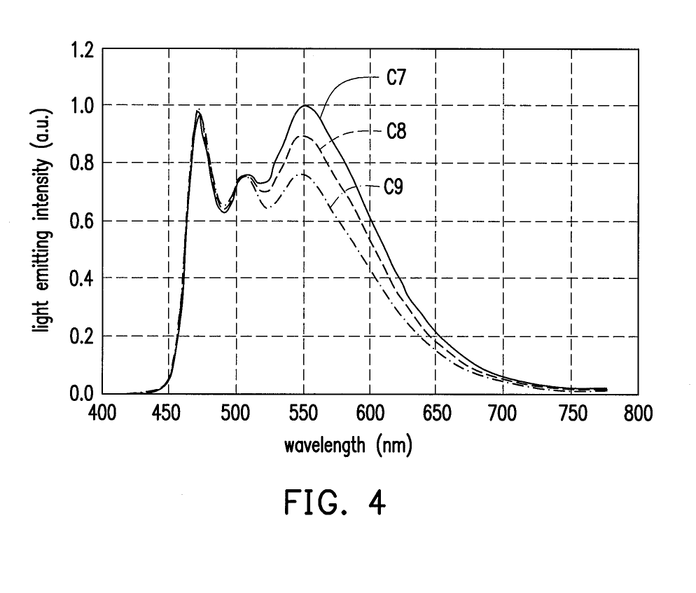

As shown in FIGS. 4, C7, C8 and C9 respectively represent the relation curves of the light emitting wavelengths and the light emitting intensity of three second light emitting units U2. Particularly, in the second light emitting units U2 represented by C7, C8 or C9, the second light emitting layer 204 has a second blue light emitting layer B2 and a green light emitting layer G, and C7, C8 and C9 represent that the percentages of the fourth host material (TCTA) of the green light emitting layer G in the second co-host material (BAlq+TCTA) are respectively 60 wt %, 80 wt %, and 100 wt %. Similarly, in the second light emitting units U2 represented by C7˜C9, except the ratios between the fourth host material and the third host material of the green light emitting layer G are different, the conditions of other membrane layer are the same.

It can be known from FIG. 4 that when the percentage of the fourth host material in the green light emitting layer G of the second light emitting unit U2 becomes lower, the intensity of green light (520 nm˜570 nm) irradiated by the second light emitting unit U2 would become stronger, and the intensity of the blue light (470 nm-480 nm) of the second light emitting unit U2 almost remains the same. In other words, by adjusting the percentages of the third host material and the fourth host material in the green light emitting layer G of the second light emitting unit U2, the intensity of the green light irradiated by the second light emitting unit U2 can be different.

Therefore, in this embodiment, by adjusting the percentages of the first host material and the second host material in the red light emitting layer R of first light emitting unit U1, the first light emitting unit U1 could irradiate the blue light with a desired intensity, and by arranging the percentages of the third host material and the fourth host material in the green light emitting layer G of the second light emitting unit U2, the second light emitting unit U2 could irradiate the green light with a desired intensity. That is, with the combinations of a specific intensity of blue light, a specific intensity of green light and a specific intensity of red light, the specific light color of white light can be obtained through light mixing.

Particularly, in this embodiment, the intensity of the blue light can be adjusted just by adjusting the percentages of the first host material and the second host material in the red light emitting layer R of the first light emitting unit U1, and the intensity of green light can be adjusted by adjusting the percentages of the third host material and the fourth host material in the green light emitting layer G of the second light emitting unit U2. Therefore, a specific light color of the white light can be easily obtained in this embodiment by adjusting the percentages of the host materials in the light emitting layers.

For example, a desired white light with low color temperature irradiated by the white light electroluminescence device can be obtained by enhancing the intensity of the red light in the first light emitting unit U1 and enhancing the intensity of the green light in the second light emitting unit U2. In contrary, a desired white light with high color temperature irradiated by the white light electroluminescence device can be obtained by enhancing the intensity of the blue light in the first light emitting unit U1 and enhancing the intensity of the blue light in the second light emitting unit U2. These modulations of light color can be achieved just by adjusting the percentages of the co-host materials in each light emitting layer.

The examples in FIG. 2 to FIG. 4 the combinations of specific materials of the red light emitting layer, the green light emitting layer and the blue light emitting layer are used as examples and described herein. However, the present invention is not limited to these examples. In other embodiments, if other combinations of materials in the red light emitting layer, the green light emitting layer and the blue light emitting layer are used, different relationships between the light emitting wavelengths and the light emitting intensity could be obtained.

Although the white light electroluminescence device of this embodiment is described as two light emitting units as an example, the number of light emitting units stacked in the white light electroluminescence device is not limited in the present invention. In other words, the number of light emitting units stacked in the white light electroluminescence devices of other embodiments can be three or more.

Although the present invention already disclosed by the embodiments described above, they do not intended to limit the present invention. It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. A white light electroluminescence device, comprising:
a first light emitting unit, comprising:
a first electrode layer; and
a first light emitting layer disposed on the first electrode layer, wherein the first light emitting layer comprises a first blue light emitting layer and a red light emitting layer, and the red light emitting layer comprises a first co-host material and a first dopant material;
a second light emitting unit, comprising:
a second light emitting layer, comprising a second blue light emitting layer and a green light emitting layer, wherein the green light emitting layer comprises a second co-host material and a second dopant material; and
a second electrode layer disposed on the second light emitting layer; and
a connecting layer disposed between the first light emitting unit and the second light emitting unit, such that the first light emitting unit and the second light emitting unit are electrically connected in series.

2. The device of claim 1, wherein the first co-host material of the red light emitting layer comprises a first host material and a second host material, and the percentage of the second host material in the first co-host material is about 5˜60 wt %.

3. The device of claim 2, wherein the second co-host material of the green light emitting layer comprises a third host material and a fourth host material, and the percentage of the fourth host material in the second co-host material is about 60˜100 wt %.

4. The device of claim 3, wherein the thickness of the green light emitting layer is 5˜35 nm, the thickness of the second blue light emitting layer is 5-30 nm, the thickness of the red light emitting layer is 5˜35 nm, and the thickness of the first blue light emitting layer is 5-20 nm.

5. The device of claim 1, wherein the percentage of the first dopant material in the red light emitting layer is about 0.5˜10 wt %.

6. The device of claim 1, wherein the second co-host material of the green light emitting layer comprises a third host material and a fourth host material, and the percentage of the fourth host material in the second co-host material is about 60˜100 wt %.

7. The device of claim 1, wherein the percentage of the second dopant material in the green light emitting layer is about 3˜25 wt %.

8. The device of claim 1, wherein the second host material of the red light emitting layer and the fourth host material of the green light emitting layer are substantially the same.

9. The device of claim 1, wherein the materials of the first blue light emitting layer and the second blue light emitting layer are substantially the same.

10. The device of claim 1, wherein the first blue light emitting layer and the second blue light emitting layer respectively comprise a host material and a dopant material, and the ratio of the host material to the dopant material is about 0.7:0.3˜0.95:0.05.

11. The device of claim 1, further comprising:
a first hole injection layer disposed between the first electrode layer and the first light emitting layer;
a first hole transport layer disposed between the first electrode layer and the first light emitting layer;
a first electron transport layer disposed between the connecting layer and the first light emitting layer;
a second hole transport layer disposed between the second light emitting layer and the connecting layer;
a second electron injection layer disposed between the second electrode layer and the second light emitting layer; and
a second electron transport layer disposed between the second light emitting layer and the second electrode layer.
